(19) United States
(12) Patent Application Publication
(10) Pub. No.: US 2024/0065057 A1
(43) Pub. Date: Feb. 22, 2024

(54) Fanout Lines with Shielding in an Active Area

(71) Applicant: Apple Inc., Cupertino, CA (US)

(72) Inventors: Shin-Hung Yeh, Taipei (TW); Abbas Jamshidi Roudbari, Saratoga, CA (US); Chien-Ya Lee, Taipei (TW); I-Cheng Shih, Taoyuan (TW); Shyuan Yang, San Jose, CA (US); Tsung-Ting Tsai, San Jose, CA (US)

(21) Appl. No.: 18/328,427

(22) Filed: Jun. 2, 2023

Related U.S. Application Data
(60) Provisional application No. 63/398,499, filed on Aug. 16, 2022.

(51) Int. Cl. H10K 59/131; H10K 59/126; H10K 59/121

(52) U.S. Cl. CPC H10K 59/131; H10K 59/126; H10K 59/1213

(57) ABSTRACT

A display may include pixels arranged in rows and columns in an active area and display driver circuitry in an inactive area. Data lines for the pixels may be positioned in the active area. Fanout lines may be routed through the active area. Each fanout line may electrically connect the display driver circuitry to a respective data line. One or more pixels may include a drive transistor and a light-emitting diode that are connected in series between a first power supply terminal and a second power supply terminal. A conductive layer may form a first terminal (such as the source terminal, the gate terminal, or the drain terminal) for the drive transistor. A conductive shielding layer may be interposed between the conductive layer and a fanout line to mitigate capacitive coupling between the terminal of the drive transistor and the fanout line.

This application claims priority to U.S. provisional patent application No. 63/398,499, filed Aug. 16, 2022, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels. In this type of display, each pixel includes a light-emitting diode and thin-film transistors for controlling application of a signal to the light-emitting diode to produce light. The light-emitting diodes may include OLED layers positioned between an anode and a cathode.

### SUMMARY

A display may include a plurality of pixels arranged in a first area, display driver circuitry in a second area, a plurality of data lines for the plurality of pixels that is in the first area, and a plurality of fanout lines that are routed through the first area. Each fanout line of the plurality of fanout lines may electrically connect the display driver circuitry to a respective data line of the plurality of data lines and a pixel in the plurality of pixels may include a first power supply terminal, a second power supply terminal, a drive transistor and a light-emitting diode that are connected in series between the first power supply terminal and the second power supply terminal, a conductive layer that forms a first terminal for the drive transistor, and a conductive shielding layer that is interposed between the conductive layer and a fanout line of the plurality of fanout lines.

A display may include a plurality of pixels arranged in a first area in rows and columns, display driver circuitry in a second area, a plurality of data lines for the plurality of pixels, a plurality of fanout lines that are routed through the first area, and a power supply mesh. The plurality of data lines may be in the first area, each column may have a respective data line of the plurality of data lines, each fanout line of the plurality of fanout lines may electrically connect the display driver circuitry to a respective data line of the plurality of data lines, each fanout line of the plurality of fanout lines may have a first portion that extends along at least a portion of a respective column and a second portion that extends along at least a portion of a respective row, the power supply mesh may include a plurality of third portions that are aligned with first portions of the fanout lines, and the power supply mesh may include a plurality of fourth portions that are aligned with second portions of the fanout lines.

A display may include a plurality of pixels arranged in a light-emitting area, a plurality of data lines in the light-emitting area, a plurality of fanout lines in the light-emitting area, a transistor having first, second, and third terminals, and a conductive shielding layer that is interposed between a fanout line of the plurality of fanout lines and at least two of the first, second, and third terminals. Each fanout line of the plurality of fanout lines may be electrically connected to a respective data line of the plurality of data lines.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3 is a diagram of an illustrative pixel circuit in accordance with some embodiments.

FIG. 4 is a top view of an illustrative display with fanout lines in an inactive area in accordance with some embodiments.

FIG. 5 is a top view of an illustrative display with fanout lines routed through an active area in accordance with some embodiments.

FIG. 6 is a top view of an illustrative display showing how the fanout lines may be aligned with portions of a power supply mesh in accordance with some embodiments.

FIG. 7 is a diagram of an illustrative pixel circuit with capacitive coupling between a vertical fanout line portion and a source terminal of a drive transistor of the pixel in accordance with some embodiments.

FIG. 8 is a top view of a portion of an illustrative display with vertical fanout line portions that extend parallel to data lines in accordance with some embodiments.

FIG. 9 is a top view of a portion of an illustrative display with vertical power supply mesh portions that extend parallel to data lines in accordance with some embodiments.

FIG. 10 is a cross-sectional side view of an illustrative display without shielding between a vertical fanout line portion and a source terminal for a drive transistor in accordance with some embodiments.

FIG. 11 is a cross-sectional side view of an illustrative display with shielding between a vertical fanout line portion and a source terminal for a drive transistor in accordance with some embodiments.

FIG. 12 is a diagram of an illustrative pixel circuit with shielding between a vertical fanout line portion and a source terminal of a drive transistor in accordance with some embodiments.

FIG. 13 is a diagram of an illustrative pixel circuit with capacitive coupling between a vertical fanout line portion and gate and drain terminals of a drive transistor in accordance with some embodiments.

FIG. 14 is a top view of a portion of an illustrative display with vertical fanout line portions that that overlap gate and drain terminals of a drive transistor without intervening shielding in accordance with some embodiments.

FIG. 15 is a top view of a portion of an illustrative display with vertical fanout line portions that that overlap gate and drain terminals of a drive transistor with intervening shielding in accordance with some embodiments.

FIG. 16 is a cross-sectional side view of an illustrative display without shielding between a vertical fanout line portion and gate and drain terminals for a drive transistor in accordance with some embodiments.

FIG. 17 is a cross-sectional side view of an illustrative display with shielding between a vertical fanout line portion and gate and drain terminals for a drive transistor in accordance with some embodiments.

FIG. 18 is a diagram of an illustrative pixel circuit with shielding between a vertical fanout line portion and gate and drain terminals of a drive transistor in accordance with some embodiments.

### DETAILED DESCRIPTION

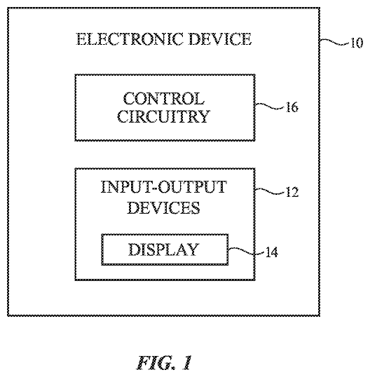

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. The control circuitry may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 12 and may receive status information and other output from device 10 using the output resources of input-output devices 12.

Input-output devices 12 may include one or more displays such as display 14. Display 14 may be a liquid crystal display, an organic light-emitting diode display, or any other desired type of display. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

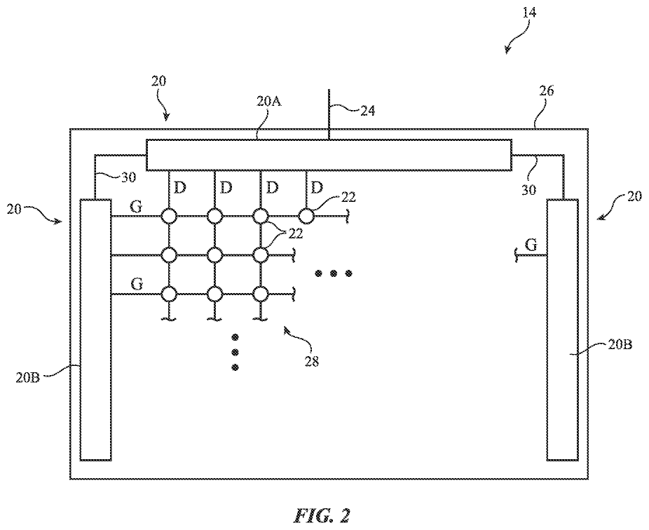

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels.

Display driver circuitry 20 may be used to control the operation of pixels 28. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

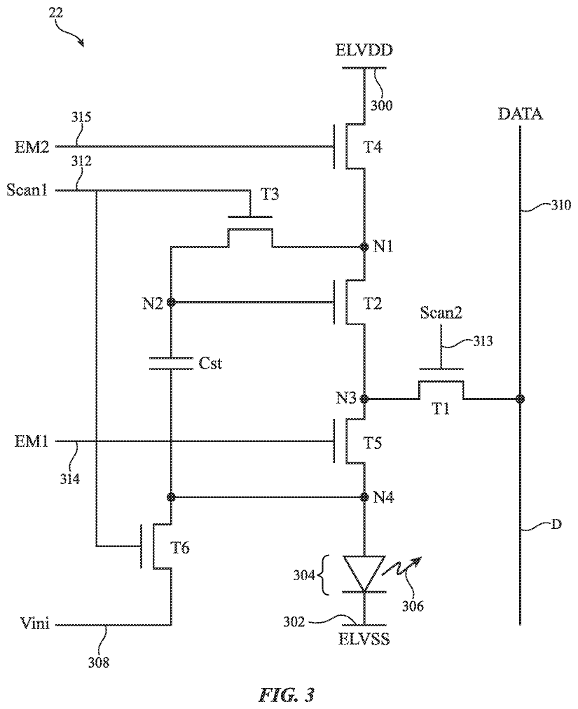

An illustrative pixel circuit of the type that may be used for each pixel 22 in array 28 is shown in FIG. 3. As shown in FIG. 3, display pixel 22 may include a storage capacitor Cst and transistors such as transistors T1, T2, T3, T4, T5, and T6. The transistors of pixel 22 may be thin-film transistors formed from a semiconductor such as silicon (e.g., polysilicon deposited using a low temperature process, sometimes referred to as LTPS or low-temperature polysilicon), semiconducting oxide (e.g., indium gallium zinc oxide (IGZO)), or other suitable semiconductor material. In other words, the active region and/or the channel region of these thin-film transistors may be formed from polysilicon or semiconducting oxide material.

Display pixel 22 may include light-emitting diode 304. A positive power supply voltage ELVDD (e.g., 1 V, 2 V, more than 1 V, 0.5 to 5 V, 1 to 10 V, or other suitable positive voltage) may be supplied to positive power supply terminal 300 and a ground power supply voltage ELVSS (e.g., 0 V, −1 V, −2 V, or other suitable negative voltage) may be supplied to ground power supply terminal 302. The power supply voltages ELVDD and ELVSS may be provided to terminals 300 and 302 from respective power supply traces. For example, a conductive layer may serve as a ground power supply voltage trace that provides the ground power supply voltage ELVSS to all of the pixels within the display. The state of transistor T2 controls the amount of current flowing from terminal 300 to terminal 302 through diode 304 and therefore controls the amount of emitted light 306 from display pixel 22. Transistor T2 is therefore sometimes referred to as the “drive transistor.” Diode 304 may have an associated parasitic capacitance C_{OLED} (not shown).

Terminal 308 is used to supply an initialization voltage Vini (e.g., a positive voltage such as 1 V, 2 V, less than 1 V, 1 to 5 V, or other suitable voltage) to assist in turning off diode 304 when diode 304 is not in use. Control signals from display driver circuitry such as gate driver circuitry 20B of FIG. 2 are supplied to control terminals such as terminals 312, 313, 314, and 315. Terminals 312 and 313 may serve respectively as first and second scan control terminals, whereas terminals 314 and 315 may serve respectively as first and second emission control terminals. Scan control signals Scan1 and Scan2 may be applied to scan terminals 312 and 313, respectively. Emission control signals EM1 and EM2 may be supplied to terminals 314 and 315, respectively. A data input terminal such as data signal terminal 310 is coupled to a respective data line D of FIG. 2 for receiving image data for display pixel 22.

Transistors T4, T2, T5, and diode 304 may be coupled in series between power supply terminals 300 and 302. Drive transistor T2 has a source terminal that is coupled to node N1, a gate terminal coupled to node N2, and a drain terminal coupled to node N3. The terms “source” and “drain” terminals of a transistor can sometimes be used interchangeably. Transistor T3, capacitor Cst, and transistor T6 are coupled in series between node N1 and terminal 308. Storage capacitor Cst has a first terminal that is coupled to node N2 and a second terminal that is coupled to node N4.

Transistor T1 is coupled between data line 310 and node N3. Connected in this way, emission control signal EM2 may be asserted to enable transistor T4 (e.g., signal EM2 may be used to turn on transistor T4); emission control signal EM1 may be asserted to activate transistor T5; scan control signal Scan2 may be asserted to turn on transistor T1; and scan control signal Scan1 may be asserted to simultaneously switch on transistors T3 and T6. Transistors T4 and T5 may sometimes be referred to as emission transistors. Transistor T6 may sometimes be referred to as an initialization transistor. Transistor T1 may sometimes be referred to as a data loading transistor.

In one possible arrangement, transistor T3 may be implemented as a semiconducting-oxide transistor while remaining transistors T1, T2, and T4-T6 are silicon transistors. Semiconducting-oxide transistors exhibit relatively lower leakage than silicon transistors, so implementing transistor T3 as a semiconducting-oxide transistor will help reduce flicker at low refresh rates (e.g., by preventing current from leaking through T3 when signal Scan1 is deasserted or driven low).

The arrangement of pixel 22 in FIG. 3 is merely illustrative, and other desired pixel arrangements be used if desired. For example, each of transistors T1-T6 may be formed from semiconducting-oxide transistors or silicon transistors. The arrangement of the connections between the transistors may be changed if desired. One or more transistors may be omitted if desired. Additional transistors may be included in the pixel if desired.

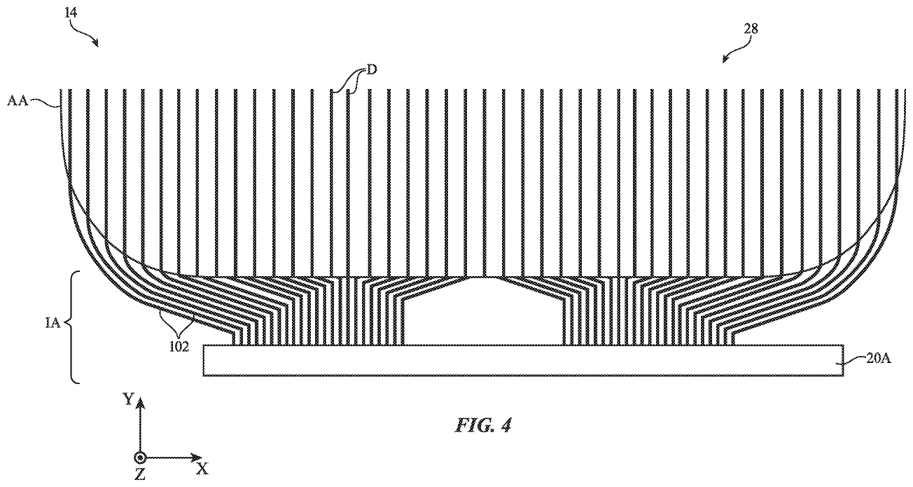

FIG. 4 is a top view of a display with fanout lines. As shown in FIG. 4, pixel array 28 may include data lines D across the width of an active area AA (sometimes referred to as light-emitting area or first area) of pixel array 28. To provide signals to data lines D, the display also includes fanout lines 102. In FIG. 4, the fanout lines are formed in an inactive area IA (sometimes referred to as non-light-emitting area or second area) of the display. Each fanout line couples a respective data signal from a respective output pin on display driver circuitry 20A to a respective data line D.

In FIG. 4, the fanout lines are contained entirely within the inactive area of the display. However, with this type of arrangement, the size of the inactive area (e.g., along the Y-dimension) has a minimum magnitude to accommodate all of the fanout lines in the inactive area. This minimum magnitude may be larger than desired (e.g., the inactive area may be larger than desired). Additionally, with the arrangement of FIG. 4, the fanout lines may require a minimum amount of space along the X-dimension (e.g., for connection to a flexible printed circuit board) that is larger than desired.

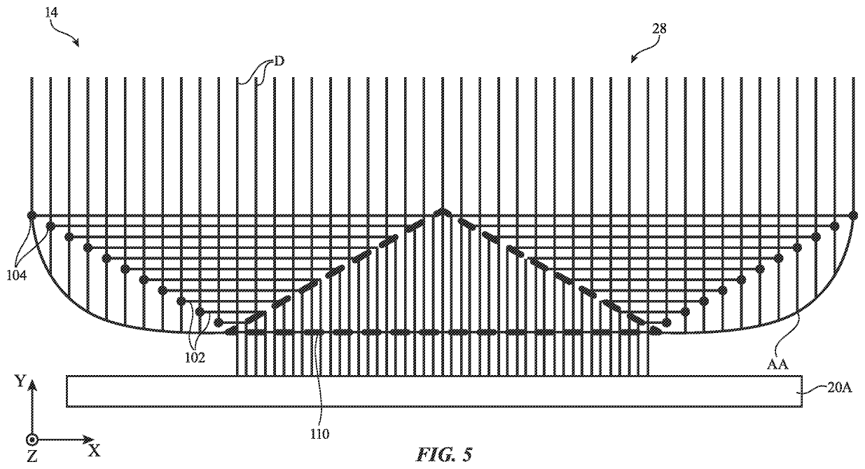

To mitigate these issues, the fanout lines may instead be formed in the active area of the display. FIG. 5 is a top view of a display with fanout lines in the active area. In FIG. 5, as in FIG. 4, each fanout line couples a respective data signal from a respective output pin on display driver circuitry 20A to a respective data line D. However, in FIG. 5, the fanout lines extend from display driver circuitry 20A (in the inactive area) into to the active area AA. The fanout lines are routed through the active area to provide signals to corresponding data lines. Each fanout line may be electrically connected to a respective data line D at a respective contact 104.

With the arrangement of FIG. 5, the minimum magnitude for the inactive area (e.g., along the Y-dimension) is reduced relative to FIG. 4. Additionally, the fanout lines may require less space along the X-dimension (e.g., for connection to a flexible printed circuit board) in FIG. 5 than in FIG. 4.

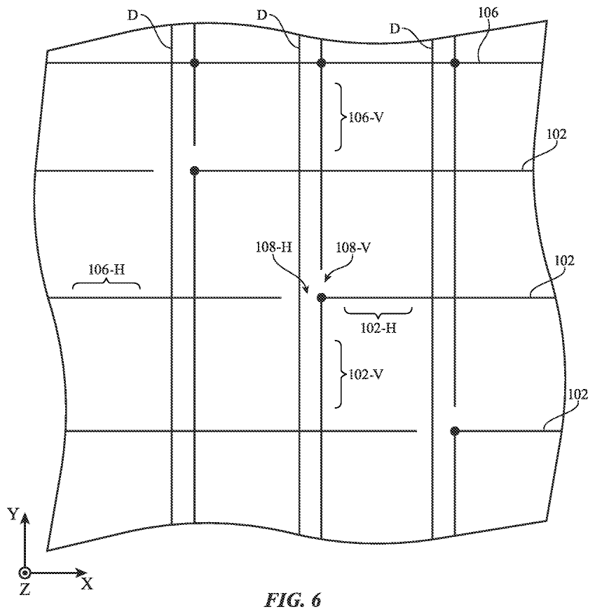

A power supply mesh may be included in the display with a complementary pattern to the pattern of fanout lines 102. For example, as previously mentioned, a conductive layer may serve as a ground power supply voltage trace that provides the ground power supply voltage ELVSS to all of the pixels within the display. FIG. 6 is a top view of a display 14 showing how a power supply mesh 106 may be included in the display. The power supply mesh 106 may provide a power supply voltage such as a ground power supply voltage to the pixels within pixel array 28.

Each fanout line 102 may include a horizontal portion 102-H (e.g., that extends parallel to the X-axis, parallel to rows of pixels in pixel array 28, parallel to gate lines Gin FIG. 2, etc.) and a vertical portion 102-V (e.g., that extends parallel to the Y-axis, parallel to columns of pixels in pixel array 28, parallel to data lines D, etc.). Power supply mesh 106 may also include horizontal portions 106-H (e.g., that extends parallel to the X-axis, parallel to rows of pixels in pixel array 28, parallel to gate lines G in FIG. 2, etc.) and a vertical portions 106-V (e.g., that extends parallel to the Y-axis, parallel to columns of pixels in pixel array 28, parallel to data lines D, etc.).

Each horizontal portion 102-H of a fanout line may be aligned with (e.g., colinear with) a corresponding horizontal portion 106-H of power supply mesh 106. In other words, a single horizontal conductive line may be formed across the entire width of the display. The single horizontal conductive line may then be patterned with one or more discontinuities (e.g., discontinuity 108-H in FIG. 6). The different segments of the horizontal conductive line then have different functions during operation of the display (e.g., portion 102-H serves as part of a fanout line and portion 106-H serves as part of a power supply mesh). If desired, the segments may be deposited to initially include the discontinuities.

Each vertical portion 102-V of a fanout line may be aligned with (e.g., colinear with) a corresponding vertical portion 106-V of power supply mesh 106. In other words, a single vertical conductive line may be formed across the entire width of the display. The single vertical conductive line may then be patterned with one or more discontinuities (e.g., discontinuity 108-V in FIG. 6). The different segments of the vertical conductive line then have different functions during operation of the display (e.g., portion 102-V serves as part of a fanout line and portion 106-V serves as part of a power supply mesh). If desired, the segments may be deposited to initially include the discontinuities.

The arrangement of FIG. 6 may reduce manufacturing cost and/or complexity (because conductive lines may be deposited in a grid across the entire display instead of in only a portion of the display for the fanout lines). Additionally, including power supply mesh 106 as in FIG. 6 ensures that the conductive signal lines have a similar density across the entire display. Without the power supply mesh (e.g., as can be seen in the top view of FIG. 5), there is a higher density of signal lines in portions of the display that include fanout lines. This may cause non-uniformity in the display, particularly when the display is turned off and light reflects off of the display. Including power supply mesh 106 therefore improves the cosmetic appearance for display 14. Yet another benefit of including power supply mesh 106 is that the power supply mesh may reduce IR drop as the power supply voltage is distributed across the display.

Returning to FIG. 5, there is an area 110 (as indicated by the dashed lines) in which vertical portions 102-V of the fanout lines 102 run parallel to data lines D. In the areas outside of area 110 (e.g., in the remainder of the display), vertical portions 106-V of the power supply mesh 106 may run parallel to data lines D. Within area 110, if care is not taken, the vertical portions 102-V of the fanout lines 102 may be capacitively coupled (e.g., via parasitic coupling) to the source, drain, and/or gate of one or more transistors within the pixels within a portion of a column overlapped by the vertical portion 102-V. For example, the vertical portions 102-V of the fanout lines 102 may be capacitively coupled to the source, drain, and/or gate of the drive transistor (e.g., T2 in FIG. 3) of each pixel within a portion of a column overlapped by the vertical portion 102-V. Capacitive coupling of this type may cause visible artifacts during operation of the display (due to the parasitic coupling to fanout line portions 102-V that is only present within area 110). To mitigate the artifacts caused by capacitive coupling between the drive transistors and the fanout line portions 102-V, shielding may be included between the fanout line portions 102-V and the drive transistors.

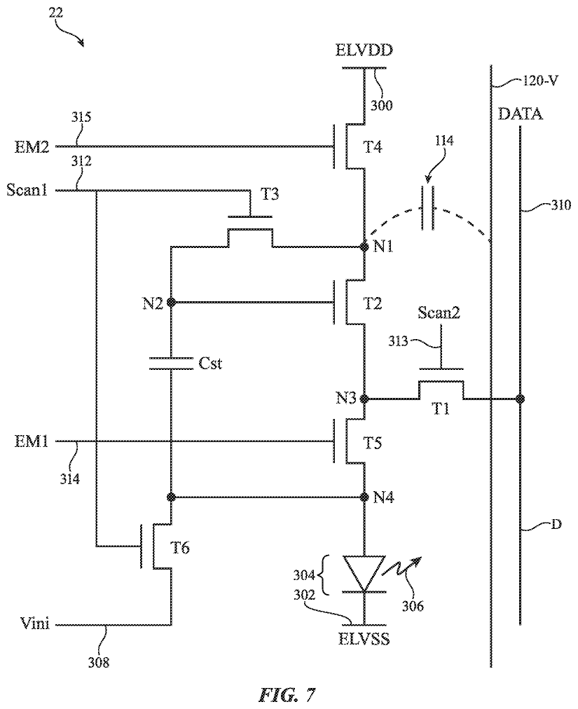

FIG. 7 is a diagram showing an illustrative pixel within area 110 of FIG. 5 when no shielding is included between node N1 and fanout line portion 102-V. As shown, without shielding there may be a parasitic capacitance 114 between the source of drive transistor T2 (e.g., node N1) and fanout line portion 102-V. To prevent capacitive coupling between node N1 and fanout line portion 102-V, a shielding layer may be interposed between node N1 and fanout line portion 102-V.

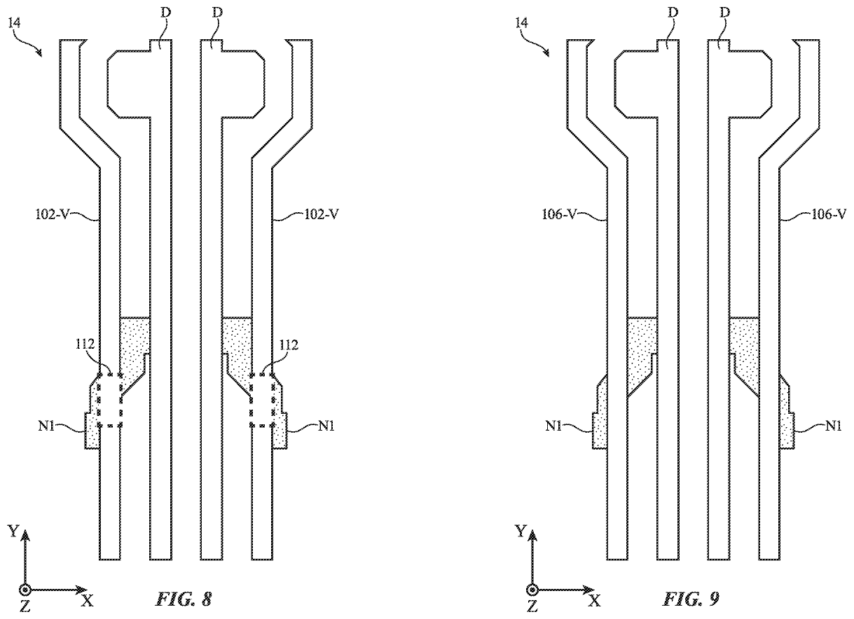

FIG. 8 is a top view of display 14 showing two adjacent columns within area 110 of FIG. 5. FIG. 9 is a top view of display 14 showing two adjacent columns outside of area 110 of FIG. 5. In FIG. 8, a vertical fanout line portion 102-V extends parallel to a data line D within each column. As shown in FIG. 8, the vertical fanout line portion 102-V overlaps node N1 of the drive transistor in regions 112. Without shielding, capacitive coupling between vertical fanout line portion 102-V and node N1 at region 112 may cause visible artifacts.

As shown in FIG. 9, outside of area 110, the pattern of signal lines is the same as in FIG. 8. However, in FIG. 9 vertical power supply mesh portions 106-V extend parallel to data lines D within each column. Each vertical power supply mesh portion 106-V overlaps node N1 of the drive transistor. However, the overlap between vertical power supply mesh portion 106-V and node N1 does not cause artifacts because vertical power supply mesh portion 106-V carries a direct current signal and does not adversely impact the drive transistor.

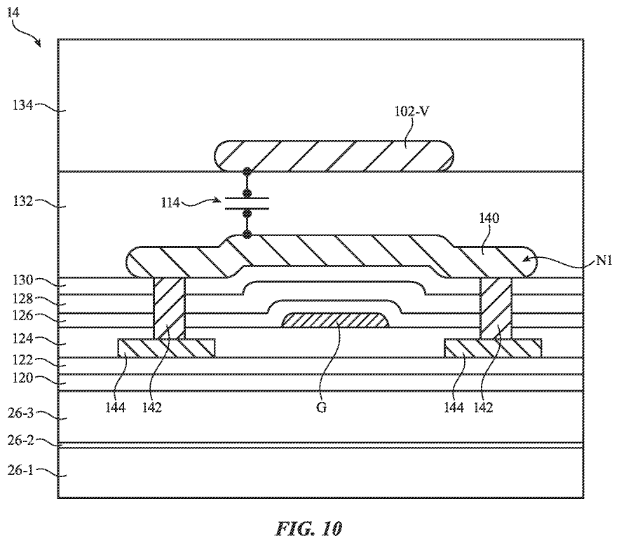

FIG. 10 is a cross-sectional side view of region 112 from FIG. 8 when no shielding is interposed between the vertical fanout line portion 102-V and node N1 of the drive transistor. As shown in FIG. 10, display 14 may include first, second, and third substrate layers 26-1, 26-2, and 26-3. The substrate layers may be formed from any desired materials. In one example, substrate layers 26-1 and 26-3 are formed from polyimide and substrate layer 26-2 is formed from silicon dioxide. One or more buffer layers (e.g., inorganic buffer layers) such as layers 120 and 122 may be formed over the substrate layers. A gate insulator layer 124 is formed over layers 120 and 122. One or more interlayer dielectric layers 126 is formed over the gate insulator layer 124. An additional buffer layer 128 is formed over interlayer dielectric layers 126. An interlayer dielectric layer 130 is formed over buffer layer 128. Planarization layers 132 and 134 may be formed over interlayer dielectric layer 130. Planarization layers 132 and 134 may be formed from organic materials and may sometimes be referred to as organic planarization layers. Each one of layers 120, 122, 124, 126, 128, 130, 132, and 134 may be referred to as a dielectric layer. Each one of layers 120, 122, 124, 126, 128, 130, 132, and 134 may be formed from any desired material (e.g., organic material or inorganic material).

As shown in FIG. 10, a gate line G (e.g., a conductive signal line) may be interposed between gate insulator layer 122 and interlayer dielectric layer(s) 124. Node N1 may include a conductive layer 140 (sometimes referred to as metal layer 140), via portions 142, and polysilicon portions 144. Conductive layer 140 is formed between interlayer dielectric layer 130 and planarization layer 132. Polysilicon portions 144 are formed on layer 122 and partially covered by gate insulator layer 124. Vias 142 extend through layers 124, 126, 128, and 130 to electrically connect conductive layer 140 to polysilicon portions 144. The arrangement of FIG. 10 allows for node N1 to have a footprint that overlaps gate line G without being electrically connected to gate line G.

As shown in FIG. 10, a vertical fanout line portion is formed between planarization layers 132 and 134. Without shielding (as in FIG. 10), the vertical fanout line portion may have capacitive coupling 114 to conductive layer 140 of node N1.

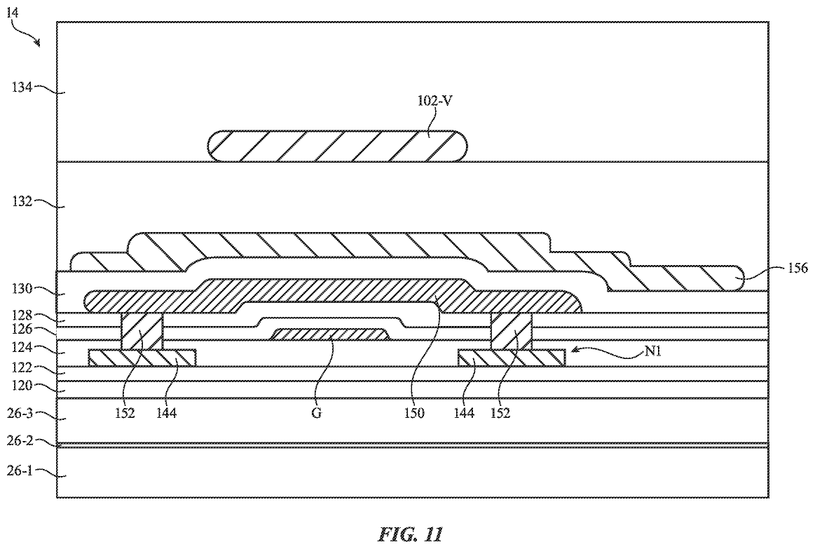

To prevent the capacitive coupling between the vertical fanout line portion and node N1, the arrangement of FIG. 11 may instead be used. As shown in FIG. 11, node N1 again includes polysilicon portions 144 that are formed on layer 122 and partially covered by gate insulator layer 124. Node N1 also includes conductive layer 150 that is interposed between dielectric layer 128 and interlayer dielectric layer 130. Node N1 also includes via portions 152. Vias 152 extend through layers 124, 126, and 128. The arrangement of FIG. 11 allows for node N1 to have a footprint that overlaps gate line G without being electrically connected to gate line G.

In FIG. 11, a vertical fanout line portion is again formed between planarization layers 132 and 134. It is noted that data lines D may also be positioned between planarization layers 132 and 134 (e.g., coplanar with vertical fanout line portion 102-V). In FIG. 11, a conductive shielding layer 156 is interposed between vertical fanout line portion 102-V and conductive layer 150 for the drive transistor terminal. Conductive shielding layer 156 is interposed between interlayer dielectric layer 130 and planarization layer 132. The conductive shielding layer 156 may be biased to a fixed voltage such as the positive power supply voltage ELVDD (as one example). With this arrangement, the overlap between vertical fanout line portion 102-V and conductive shielding layer 156 and the overlap between conductive shielding layer 156 and conductive layer 150 does not cause artifacts because conductive shielding layer 156 carries a direct current signal and therefore does not impact the drive transistor.

Every pixel within region 110 in FIG. 5 may have the arrangement of FIG. 11 between the node N1 (for the drive transistor) and the vertical fanout line portion 102-V. The footprints of conductive layer 150, shielding layer 156, and vertical fanout line portion 102-V may overlap when viewed from above (e.g., from a direction parallel to the surface normal of the display).

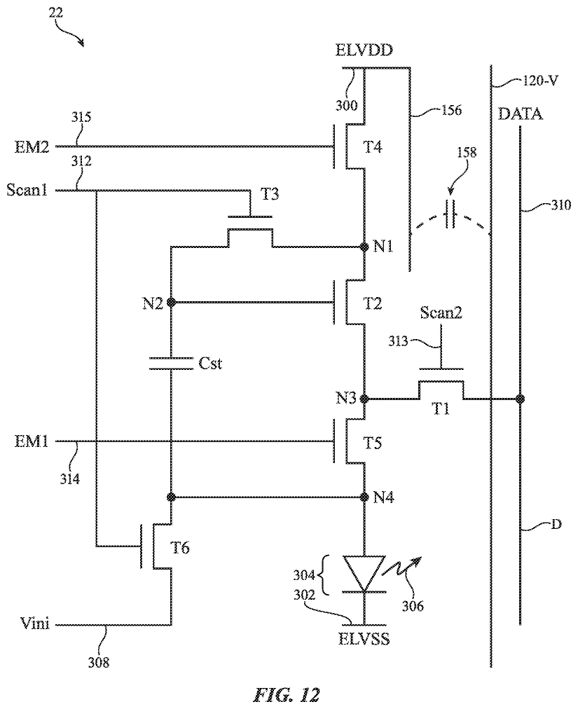

FIG. 12 is a pixel circuit for a pixel that includes shielding as shown in FIG. 11. As shown in FIG. 12, the additional shielding layer causes vertical fanout line portion 102-V to parasitically couple to shielding layer 156 (as shown by capacitance 158 in FIG. 12). However, shielding layer 156 is coupled to positive power supply terminal 300 and is therefore biased to positive power supply voltage ELVDD. The parasitic coupling between vertical fanout line portion 102-V and shielding layer 156 therefore does not adversely impact the performance of pixel 22.

FIGS. 11 and 12 show how shielding may be used to mitigate capacitive coupling between a fanout line and a first drive transistor terminal (e.g., a source terminal at node N1). However, shielding may instead or in addition be used to mitigate capacitive coupling between a fanout line and second and third drive transistor terminals (e.g., a gate terminal at node N2 and a drain terminal at node N3).

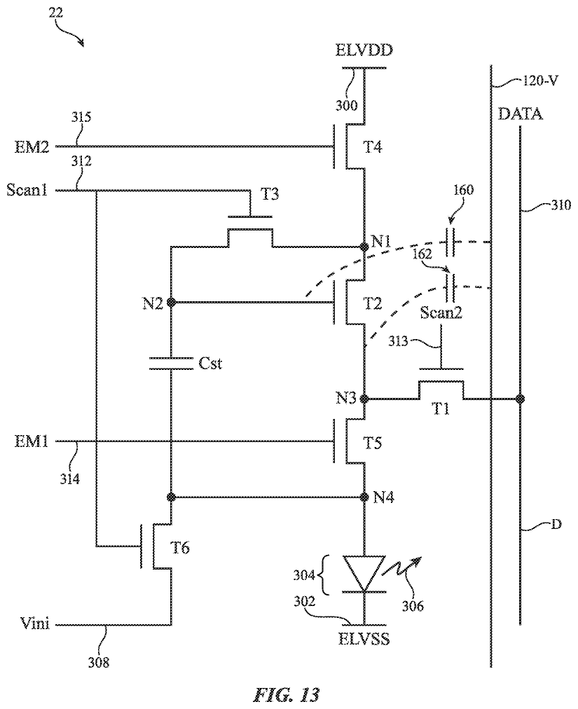

FIG. 13 is a pixel circuit showing a first capacitive coupling 160 between the gate terminal of drive transistor T2 (at node N2) and fanout line portion 102-V and a second capacitive coupling 162 between the drain terminal of drive transistor T2 (at node N3) and fanout line portion 102-V. This capacitive coupling may cause visible artifacts during display operation.

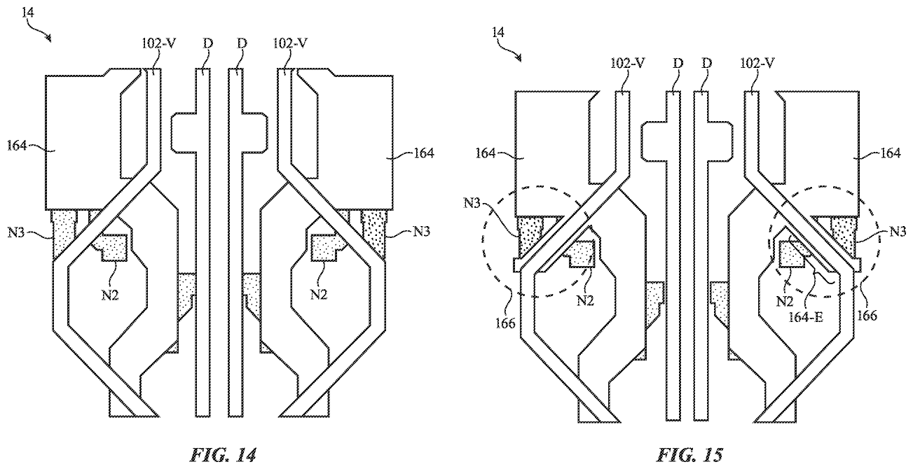

FIG. 14 is a top view of an illustrative display 14 showing two adjacent columns within a fanout line region in the active area (e.g., area 110 of FIG. 5). As shown in FIG. 14, the vertical fanout line portion 102-V overlaps nodes N2 and N3 of the drive transistor. Without shielding (as in FIG. 14), capacitive coupling between vertical fanout line portion 102-V and nodes N2 and N3 may cause visible artifacts.

FIG. 14 additional shows how a conductive layer 164 may be included within each column. The conductive layer 164 may be coupled to a power supply voltage such as the positive power supply voltage ELVDD (as one example).

FIG. 15 is a top view of an illustrative display 14 showing two adjacent columns with shielding between a vertical fanout line portion 102-V and nodes N2 and N3 of the drive transistor. In the example of FIG. 14, conductive layer 164 does not overlap nodes N2 and N3 of the drive transistor within each column. To provide shielding of capacitive coupling between the vertical fanout line portions and nodes N2 and N3, the conductive layer 164 may be extended in regions 166 to overlap portions of vertical fanout line portion 102-V. As shown in FIG. 15, an extension 164-E of conductive layer 164 overlaps all portions of vertical fanout line portion 102-V that overlap nodes N3 and N2.

It is noted that outside of area 110 (e.g., where vertical fanout line portions are not present), the footprint of the display may be the same as in FIG. 14, except with vertical power supply mesh portions 106-V extending parallel to data lines D within each column (instead of vertical fanout line portions 102-V). The extension 164-E of conductive layer 164 may be omitted in these portions of the display because overlap between vertical power supply mesh portions 106-V and nodes N2 and N3 will not cause visible artifacts. Alternatively, the extension 164-E of conductive layer 164 may be included in these portions of the display to simplify manufacturing (even though the extension is not needed for shielding of capacitive coupling).

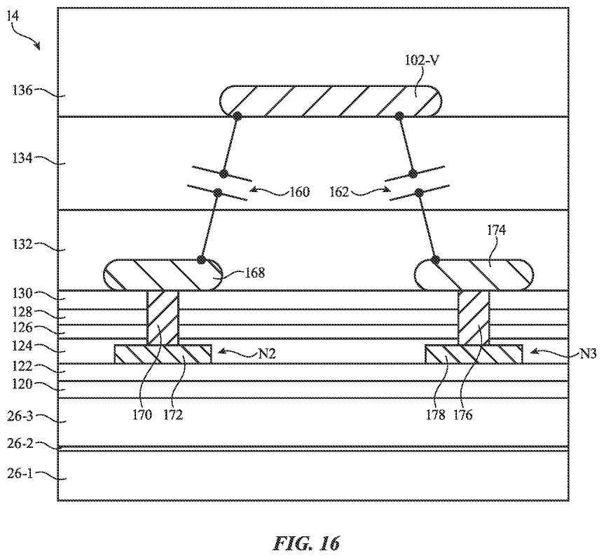

FIG. 16 is a cross-sectional side view of the display in FIGS. 13 and 14 when no shielding is interposed between the vertical fanout line portion 102-V and nodes N2 and N3 of the drive transistor. Similar to as in FIGS. 10 and 11, the display in FIG. 16 includes substrate layers 26-1, 26-2, and 26-3 as well as dielectric layers 120, 122, 124, 126, 128, 130, 132, and 134. The display in FIG. 16 also includes an additional planarization layer 136 relative to the display in FIGS. 10 and 11. Planarization layer 136 may be formed from organic material and may sometimes be referred to as an organic planarization layer.

As shown in FIG. 16, a second terminal for the drive transistor (e.g., the gate terminal at node N2) may include a conductive layer 168 (sometimes referred to as metal layer 168), a via 170, and a polysilicon layer 172. Conductive layer 168 is interposed between the interlayer dielectric layer 130 and planarization layer 132. Polysilicon layer 172 is formed on dielectric layer 122 and is at least partially covered by dielectric layer 124. Via 170 extends through dielectric layers 124, 126, 128, and 130 to electrically connect conductive layer 168 and polysilicon layer 172.

As shown in FIG. 16, a third terminal for the drive transistor (e.g., the drain terminal at node N3) may include a conductive layer 174 (sometimes referred to as metal layer 174), a via 176, and a polysilicon layer 178. Conductive layer 174 is interposed between the interlayer dielectric layer 130 and planarization layer 132. Polysilicon layer 178 is formed on dielectric layer 122 and is at least partially covered by dielectric layer 124. Via 176 extends through dielectric layers 124, 126, 128, and 130 to electrically connect conductive layer 174 and polysilicon layer 178. Polysilicon layers 172 and 178 in FIG. 16 are coplanar. Conductive layers 168 and 174 in FIG. 16 are coplanar.

As shown in FIG. 16, a vertical fanout line portion is formed between planarization layers 134 and 136. Without shielding (as in FIG. 16), the vertical fanout line portion may have capacitive coupling 160 to conductive layer 168 of node N2. Without shielding (as in FIG. 16), the vertical fanout line portion may have capacitive coupling 162 to conductive layer 174 of node N3.

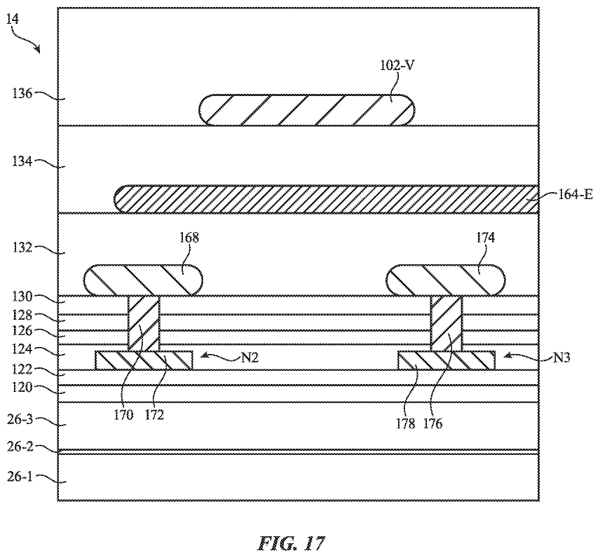

To prevent the capacitive coupling between the vertical fanout line portion and nodes N2 and N3, the arrangement of FIG. 17 may instead be used. As shown in FIG. 17, node N2 again includes polysilicon 172, via portion 170, and conductive layer 168. Node N3 again includes polysilicon 178, via portion 176, and conductive layer 174.

In FIG. 17, a vertical fanout line portion is again formed between planarization layers 134 and 136. It is noted that data lines D may also be positioned between planarization layers 134 and 136 (e.g., coplanar with vertical fanout line portion 102-V). In FIG. 17, a conductive shielding layer 164-E is interposed between vertical fanout line portion 102-V and conductive layer 168 for the drive transistor gate terminal (at node N2). The conductive shielding layer 164-E is also interposed between vertical fanout line portion 102-V and conductive layer 174 for the drive transistor drain terminal (at node N3). Conductive shielding layer 164-E is interposed between planarization layer 132 and planarization layer 134. As previously discussed in connection with FIG. 15, the conductive shielding layer 164-E may be an extension of a conductive layer 164 that is biased to a fixed voltage such as the positive power supply voltage ELVDD (as one example). With this arrangement, the overlap between vertical fanout line portion 102-V and conductive shielding layer 164-E and the overlap between conductive shielding layer 164-E and conductive layers 168 and 174 does not cause artifacts because conductive shielding layer 164-E carries a direct current signal and therefore does not impact the drive transistor.

Every pixel within region 110 in FIG. 5 may have the arrangement of FIG. 17 between the node N1 (for the drive transistor) and the vertical fanout line portion 102-V. The footprints of conductive layer 168, shielding layer 164-E, and vertical fanout line portion 102-V may overlap when viewed from above (e.g., from a direction parallel to the surface normal of the display). The footprints of conductive layer 174, shielding layer 164-E, and vertical fanout line portion 102-V may overlap when viewed from above (e.g., from a direction parallel to the surface normal of the display).

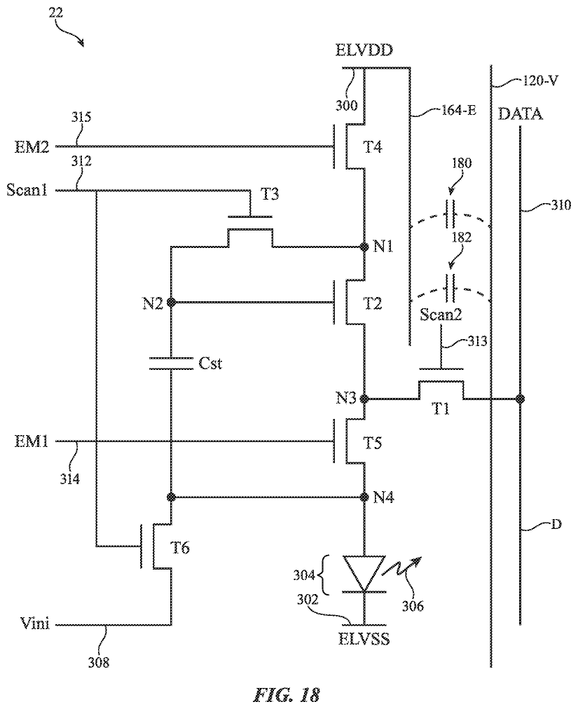

FIG. 18 is a pixel circuit for a pixel that includes shielding as shown in FIG. 17. As shown in FIG. 18, the additional shielding layer causes vertical fanout line portion 102-V to parasitically couple to shielding layer 164-E (as shown by capacitances 180 and 182 in FIG. 12) instead of nodes N2 and N3 as in FIG. 13. Shielding layer 164-E is coupled to positive power supply terminal 300 and is therefore biased to positive power supply voltage ELVDD. The parasitic coupling between vertical fanout line portion 102-V and shielding layer 164-E therefore does not adversely impact the performance of pixel 22.

FIG. 11 shows an example of a conductive shielding layer that is interposed between a first terminal (e.g., the source terminal) of the drive transistor and the fanout line. FIG. 11 also shows an example where the conductive shielding layer is interposed between dielectric layers 130 and 132. FIG. 17 shows an example of a conductive shielding layer that is interposed between second and third terminals (e.g., the gate and drain terminals) of the drive transistor and the fanout line. FIG. 17 also shows an example where the conductive shielding layer is interposed between dielectric layers 132 and 134. In general, these possible arrangements for conductive shielding may be included in the display in any combination. For example, a single display may have conductive shielding that overlaps each one of the first, second, and third terminals of the drive transistor for each pixel within region 110. Alternatively, the conductive shielding may only overlap any one or any two of the first, second, and third terminals of the drive transistor for each pixel within region 110. The conductive shielding may be contained within one layer of the display stack (as in FIGS. 11 and 17, individually). Alternatively, there may be conductive shielding at multiple layers within a single display (e.g., the conductive shielding of FIG. 11 and the conductive shielding of FIG. 17 may be used in a single display).

The concept herein of shielding a transistor in a pixel may apply to any pixel with a transistor. Any type of transistor may be shielded (e.g., a drive transistor, a switching transistor, an emission transistor, etc.) and the pixel may include any other desired number of transistors (e.g., zero additional transistors, one additional transistor, more than one additional transistor, etc.).

The foregoing is merely illustrative and various modifications can be made by those skilled in the art without departing from the scope and spirit of the described embodiments. The foregoing embodiments may be implemented individually or in any combination.

What is claimed is:

1. A display comprising:
a plurality of pixels arranged in a first area;
display driver circuitry in a second area;
a plurality of data lines for the plurality of pixels, wherein the plurality of data lines is in the first area; and
a plurality of fanout lines that are routed through the first area, wherein each fanout line of the plurality of fanout lines electrically connects the display driver circuitry to a respective data line of the plurality of data lines and wherein a pixel in the plurality of pixels comprises:
a first power supply terminal;
a second power supply terminal;
a drive transistor and a light-emitting diode that are connected in series between the first power supply terminal and the second power supply terminal;
a conductive layer that forms a first terminal for the drive transistor; and
a conductive shielding layer that is interposed between the conductive layer and a fanout line of the plurality of fanout lines.

2. The display defined in claim 1, wherein the first terminal is a source terminal.

3. The display defined in claim 1, wherein the first terminal is a gate terminal.

4. The display defined in claim 1, wherein the first terminal is a drain terminal.

5. The display defined in claim 1, wherein the pixel further comprises:
a first dielectric layer that is interposed between the conductive shielding layer and the fanout line; and
a second dielectric layer that is interposed between the conductive layer and the conductive shielding layer.

6. The display defined in claim 5, wherein the first dielectric layer is an organic planarization layer.

7. The display defined in claim 5, wherein the first dielectric layer is in direct contact with both the conductive shielding layer and the fanout line and wherein the second dielectric layer is in direct contact with both the conductive layer and the conductive shielding layer.

8. The display defined in claim 5, wherein the pixel further comprises:
a third dielectric layer;
a fourth dielectric layer; and
a fifth dielectric layer, wherein a gate line is interposed between the fourth and fifth dielectric layers.

9. The display defined in claim 8, wherein the pixel further comprises:
first and second polysilicon layers; and
first and second vias that extend through the third, fourth, and fifth dielectric layers to electrically connect the conductive layer to the first and second polysilicon layers, wherein the conductive layer, the first and second polysilicon layers, and the first and second vias collectively make up the first terminal for the drive transistor.

10. The display defined in claim 5, wherein the first dielectric layer is a first organic planarization layer and wherein the second dielectric layer is a second organic planarization layer.

11. The display defined in claim 5, wherein the pixel further comprises:
a third dielectric layer;
a fourth dielectric layer;
a fifth dielectric layer;
a sixth dielectric layer;
a first polysilicon layer; and
a first via that extends through the third, fourth, fifth, and sixth dielectric layers to electrically connect the conductive layer to the first polysilicon layer, wherein the conductive layer, the first polysilicon layer, and the first via collectively make up the first terminal for the drive transistor.

12. The display defined in claim 11, wherein the pixel further comprises:
an additional conductive layer;
a second polysilicon layer; and
a second via that extends through the third, fourth, fifth, and sixth dielectric layers to electrically connect the additional conductive layer to the second polysilicon layer, wherein the additional conductive layer, the second polysilicon layer, and the second via collectively make up a second terminal for the drive transistor.

13. The display defined in claim 1, wherein the pixel further comprises:
an additional conductive layer that forms a second terminal for the drive transistor, wherein the conductive shielding layer is interposed between the additional conductive layer and the fanout line.

14. The display defined in claim 13, wherein the additional conductive layer is coplanar with the conductive layer.

15. The display defined in claim 14, wherein the first terminal is a gate terminal and wherein the second terminal is a drain terminal.

16. The display defined in claim 1, wherein the conductive shielding layer is electrically connected to the first power supply terminal.

17. The display defined in claim 1, wherein the plurality of pixels is arranged in rows and columns, wherein each column has a respective data line of the plurality of data lines, and wherein each fanout line of the plurality of fanout lines has a vertical portion that extends along at least a portion of a respective column and a horizontal portion that extends along at least a portion of a respective row.

18. The display defined in claim 17, further comprising:
a power supply mesh that includes the second power supply terminal, wherein the power supply mesh includes a plurality of vertical portions that are aligned with vertical portions of the fanout lines and wherein the power supply mesh includes a plurality of horizontal portions that are aligned with horizontal portions of the fanout lines.

19. A display comprising:
a plurality of pixels arranged in a first area, wherein the plurality of pixels is arranged in rows and columns;
display driver circuitry in a second area;
a plurality of data lines for the plurality of pixels, wherein the plurality of data lines is in the first area and wherein each column has a respective data line of the plurality of data lines;
a plurality of fanout lines that are routed through the first area, wherein each fanout line of the plurality of fanout lines electrically connects the display driver circuitry to a respective data line of the plurality of data lines and wherein each fanout line of the plurality of fanout lines has a first portion that extends along at least a portion of a respective column and a second portion that extends along at least a portion of a respective row; and
a power supply mesh, wherein the power supply mesh includes a plurality of third portions that are aligned with first portions of the fanout lines and wherein the power supply mesh includes a plurality of fourth portions that are aligned with second portions of the fanout lines.

20. A display comprising:
a plurality of pixels arranged in a light-emitting area;
a plurality of data lines in the light-emitting area;
a plurality of fanout lines in the light-emitting area, wherein each fanout line of the plurality of fanout lines is electrically connected to a respective data line of the plurality of data lines;
a transistor having first, second, and third terminals; and
a conductive shielding layer that is interposed between a fanout line of the plurality of fanout lines and at least two of the first, second, and third terminals.
